(19) United States
(12) Patent Application Publication
(10) Pub. No.: US 2026/0237600 A1
(43) Pub. Date: Aug. 13, 2026

(54) CHARGED-PARTICLE BEAM IRRADIATION APPARATUS AND CHARGED-PARTICLE BEAM IRRADIATION METHOD

(71) Applicant: NuFlare Technology, Inc., Yokohama-shi (JP)

(72) Inventors: Kei HASEGAWA, Yokohama (JP); Takuya MATSUKAWA, Yokohama (JP); Hikaru YAMAMURA, Yokohama (JP); Koji URUSHIZAKI, Yokohama (JP); Sei HATTORI, Yokohama (JP); Ryoh KAWANA, Yokohama (JP)

(73) Assignee: NuFlare Technology, Inc., Yokohama-shi (JP)

(21) Appl. No.: 19/530,609

(22) Filed: Feb. 5, 2026

(30) Foreign Application Priority Data
Feb. 10, 2025 (JP) 2025-019926

(51) Int. Cl. H01J 37/304; H01J 37/147; H01J 37/153; H01J 37/317

(52) U.S. Cl. CPC H01J 37/304; H01J 37/1472; H01J 37/153; H01J 37/3174; H01J 2237/153

(57) ABSTRACT

A charged-particle beam irradiation apparatus includes a deflector, a shot data generator generating shot data including a shot number of a charged-particle beam, a deflection controller controlling deflection of the charged-particle beam, a stage controller, an irradiation controller controlling irradiation of the charged-particle beam based on the shot data, and a storage controller configured to, when the irradiation of the charged-particle beam is stopped due to an abnormality occurring in a constituent element other than the irradiation controller, which includes at least one of the shot data generator, the deflection controller, and the stage controller, cause a storage to store therein at least the shot number at the stop of the irradiation, wherein when a condition for resuming the irradiation is satisfied, the irradiation controller resumes the irradiation from a shot number next to the shot number stored in the storage at the stop of the irradiation.

### CROSS-REFERENCE TO RELATED APPLICATIONS

This application is based upon and claims the benefit of priority from Japanese Patent Application No. 2025-019926, filed on February 10, 2025, the entire contents of which are incorporated herein by reference.

### FIELD

The present invention relates to a charged-particle beam irradiation apparatus and a charged-particle beam irradiation method.

### BACKGROUND

A conventional electron beam writing apparatus abnormally ends writing onto a mask and issues an error message indicating the content of abnormality, when writing can no longer be continued due to a momentary abnormal operation of hardware, infrequently occurring bugs, and the like.

### SUMMARY

However, the conventional electron beam writing apparatus has a problem that, in a case where writing has been abnormally ended, the apparatus cannot continue writing onto the mask with a pattern partially written, and the mask has to be discarded.

It is an object of the present invention to provide a charged-particle beam irradiation apparatus and a charged-particle beam irradiation method that can appropriately resume writing onto a sample for which writing has been abnormally ended.

A charged-particle beam irradiation apparatus according to one aspect of the present invention comprises: a deflector configured to deflect a charged-particle beam irradiated onto a sample placed on a stage; a shot data generator configured to generate shot data including a shot number of the charged-particle beam based on writing data; a deflection controller configured to control deflection of the charged-particle beam by the deflector; a stage controller configured to control movement of the stage; an irradiation controller configured to control irradiation of the charged-particle beam by controlling operations of the deflection controller and the stage controller based on the shot data generated by the shot data generator; and a storage controller configured to, when the irradiation of the charged-particle beam is stopped due to an abnormality occurring in a constituent element that is other than the irradiation controller among a plurality of constituent elements of the charged-particle beam irradiation apparatus and that includes at least one of the shot data generator, the deflection controller, and the stage controller, cause a storage to store therein at least the shot number at the stop of the irradiation, wherein when a condition for resuming the irradiation of the charged-particle beam is satisfied, the irradiation controller resumes the irradiation of the charged-particle beam from a shot number next to the shot number stored in the storage at the stop of the irradiation.

A charged-particle beam irradiation method according to one aspect of the present invention irradiates a charged-particle beam by using a charged-particle beam irradiation apparatus including: a deflector configured to deflect the charged-particle beam irradiated onto a sample placed on a stage; a shot data generator configured to generate shot data including a shot number of the charged-particle beam based on writing data; a deflection controller configured to control deflection of the charged-particle beam by the deflector; a stage controller configured to control movement of the stage; and an irradiation controller configured to control irradiation of the charged-particle beam by controlling operations of the deflection controller and the stage controller based on the shot data generated by the shot data generator, wherein the irradiation of the charged-particle beam includes: when the irradiation of the charged-particle beam is stopped due to an abnormality occurring in a constituent element that is other than the irradiation controller among a plurality of constituent elements of the charged-particle beam irradiation apparatus and that includes at least one of the shot data generator, the deflection controller, and the stage controller, causing a storage to store therein at least the shot number at the stop of the irradiation; and when a condition for resuming the irradiation of the charged-particle beam is satisfied, resuming the irradiation of the charged-particle beam from a shot number next to the shot number stored in the storage at the stop of the irradiation.

According to the present invention, it is possible to appropriately resume writing onto a sample for which writing has been abnormally ended.

### BRIEF DESCRIPTION OF THE DRAWINGS

FIG. 1 is a diagram illustrating a configuration example of a writing apparatus according to a first embodiment;

FIG. 2 is a plan view illustrating a shaping-aperture array substrate of the writing apparatus according to the first embodiment;

FIG. 3 is a cross-sectional view illustrating a blanking-aperture array substrate of the writing apparatus according to the first embodiment;

FIG. 4 is a plan view illustrating an overall configuration of a blanking-aperture array mechanism in the writing apparatus according to the first embodiment;

FIG. 5 is a diagram illustrating a configuration of an individual blanking mechanism of the blanking-aperture array mechanism in the writing apparatus according to the first embodiment;

FIG. 6 is a diagram illustrating an example of a writing operation of the writing apparatus according to the first embodiment;

FIG. 7 is a diagram illustrating an example of an irradiation region of the writing apparatus according to the first embodiment and a writing target pixel;

FIG. 8 is a diagram illustrating an example of a multi-writing operation of the writing apparatus according to the first embodiment;

FIG. 9 is a flowchart illustrating an operation example of the writing apparatus according to the first embodiment;

FIG. 10 is a diagram illustrating a configuration example of a writing apparatus according to a second embodiment;

FIG. 11 is a flowchart illustrating an operation example of the writing apparatus according to the second embodiment;

FIG. 12 is a diagram illustrating a configuration example of a writing apparatus according to a third embodiment;

FIG. 13 is a flowchart illustrating an operation example of the writing apparatus according to the third embodiment;

FIG. 14 is a flowchart illustrating an operation example of the writing apparatus according to the third embodiment in continuation from FIG. 13;

FIG. 15 is a diagram illustrating a configuration of a writing apparatus according to a first modification of the third embodiment;

FIG. 16 is a flowchart illustrating an operation of the writing apparatus according to the first modification of the third embodiment;

FIG. 17 is a diagram illustrating a configuration of a writing apparatus according to a second modification of the third embodiment;

FIG. 18 is a flowchart illustrating an operation of the writing apparatus according to the second modification of the third embodiment;

FIG. 19 is a diagram illustrating a configuration example of a writing apparatus according to a fourth embodiment;

FIG. 20 is a flowchart illustrating an operation example of the writing apparatus according to the fourth embodiment;

FIG. 21 is a diagram illustrating a configuration of a writing apparatus according to a modification of the fourth embodiment; and

FIG. 22 is a diagram illustrating an operation of the writing apparatus according to the modification of the fourth embodiment.

### DETAILED DESCRIPTION

The following descriptions are provided as to a configuration of a writing apparatus that writes a pattern onto a sample by using an electron beam as an example of a charged-particle beam irradiation apparatus according to embodiments. However, the charged particle beam in the following descriptions is not limited to an electron beam, and may be a beam using charged particles such as an ion beam. Further, the charged-particle beam irradiation apparatus is not limited to a writing apparatus, and may be a pattern inspection apparatus.

### First embodiment

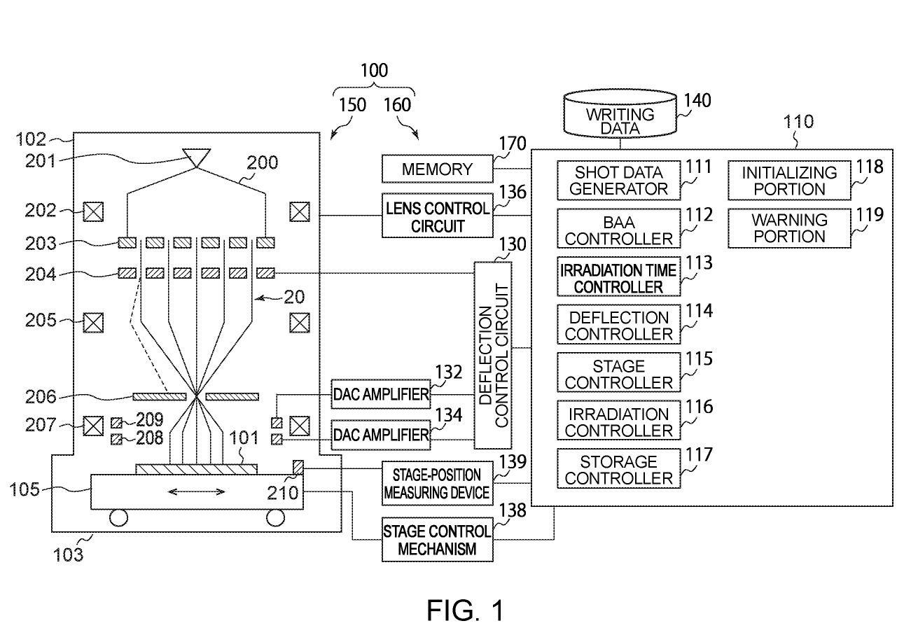

FIG. 1 is a diagram illustrating a configuration example of a writing apparatus 100 according to a first embodiment. As illustrated in FIG. 1, the writing apparatus 100 includes a writing mechanism 150 and a control system circuit 160. In the example illustrated in FIG. 1, the writing apparatus 100 is a multi-electron beam writing apparatus that performs writing by using multiple beams as an electron beam. The writing mechanism 150 includes an electron optical column 102 and a writing chamber 103. In the electron optical column 102, an electron gun 201, an illumination lens 202, a shaping-aperture array substrate 203, a blanking-aperture array mechanism 204, a reduction lens 205, a limiting-aperture substrate 206, an objective lens 207, a main deflector 208, and a sub-deflector 209 are arranged. An X-Y stage 105 is arranged in the writing chamber 103. A sample 101 such as a mask serving as a writing target substrate during writing (i.e., during exposure) is placed on the X-Y stage 105. The main deflector 208 and the sub-deflector 209 deflect the electron beam (i.e., the multiple beams) irradiated to the sample 101 arranged on the X-Y stage 105. Examples of the sample 101 include a mask for exposure when semiconductor devices are manufactured and a semiconductor substrate (a silicon wafer) on which the semiconductor devices are manufactured. The sample 101 has a resist applied thereon. For example, the sample 101 includes a mask blank that has a resist applied thereon but does not have any pattern written thereon. Further, a mirror 210 for measuring the position of the X-Y stage 105 is arranged on the X-Y stage 105.

The control system circuit 160 includes a control computer 110, a memory 170 (i.e., a storage), a deflection control circuit 130, digital-analog conversion (DAC) amplifier units 132 and 134, a lens control circuit 136, a stage control mechanism 138, a stage-position measuring device 139, and a storage device 140 such as a magnetic disk device. The control computer 110, the memory 170, the deflection control circuit 130, the lens control circuit 136, the stage control mechanism 138, the stage-position measuring device 139, and the storage device 140 are mutually connected via buses (not illustrated). The DAC amplifier units 132 and 134 and the blanking-aperture array mechanism 204 are connected to the deflection control circuit 130. The sub-deflector 209 is configured by four or more electrodes. The sub-deflector 209 is controlled by the deflection control circuit 130 via the DAC amplifier 132 for each electrode. The main deflector 208 is configured by four or more electrodes. The main deflector 208 is controlled by the deflection control circuit 130 via the DAC amplifier 134 for each electrode. The stage-position measuring device 139 receives reflected light from the mirror 210, thereby measuring the position of the X-Y stage 105 in accordance with the principle of laser interferometry.

The control computer 110 includes a shot data generator 111, a blanking-aperture array (BAA) controller 112, an irradiation time controller 113, a deflection controller 114, a stage controller 115, an irradiation controller 116, a storage controller 117, an initializing portion 118, and a warning portion 119. Each of the constituent elements 111 to 119 of the control computer 110 is configured by hardware, for example. Examples of the hardware include a processor, an electrical circuit, a computer, a circuit substrate, a quantum circuit, and a semiconductor device. At least a part of the constituent elements 111 to 119 may be configured by software (i.e., a program). Information input and output to/from each of the constituent elements 111 to 119 and information being processed are stored in the memory 170 on each occasion.

Writing data is input to the storage device 140 from outside of the writing apparatus 100 and stored in the storage device 140. The writing data includes chip data and writing condition data. In the chip data, a shape code, coordinates, and a size are defined for each shape pattern, for example. The writing condition data includes information indicating multiplicity and a stage speed. In a case of configuring each of the constituent elements 111 to 119 of the control computer 110 by a processor, a program that implements the function of each of the constituent elements 111 to 119 may be stored in the storage device 140. In this case, the processor implements the function of each of the constituent elements 111 to 119 by reading and executing the program stored in the storage device 140.

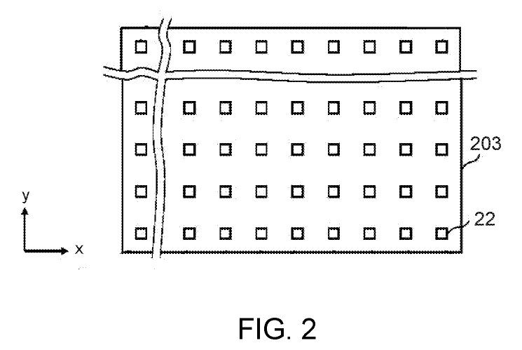

FIG. 2 is a plan view illustrating the shaping-aperture array substrate 203 of the writing apparatus 100 according to the first embodiment. In the example illustrated in FIG. 2, the shaping-aperture array substrate 203 has holes (i.e., openings) 22 formed therein in a matrix of p columns in the vertical direction (y direction) × q rows in the horizontal direction (x direction), where p and q are 2 or more. FIG. 2 illustrates a case where the holes 22 are formed in 32 rows × 32 columns in the horizontal and vertical directions (x and y directions). The number of holes 22 is not limited to the example illustrated in FIG. 2. The holes 22 are all formed to have the same rectangular shape with the same dimensions. Alternatively, the shape of the holes 22 may be circular and have the same diameter. Portions of an electron beam 200 pass through the respective holes 22, so that multiple beams 20 are formed. In other words, the shaping-aperture array substrate 203 forms the multiple beams 20.

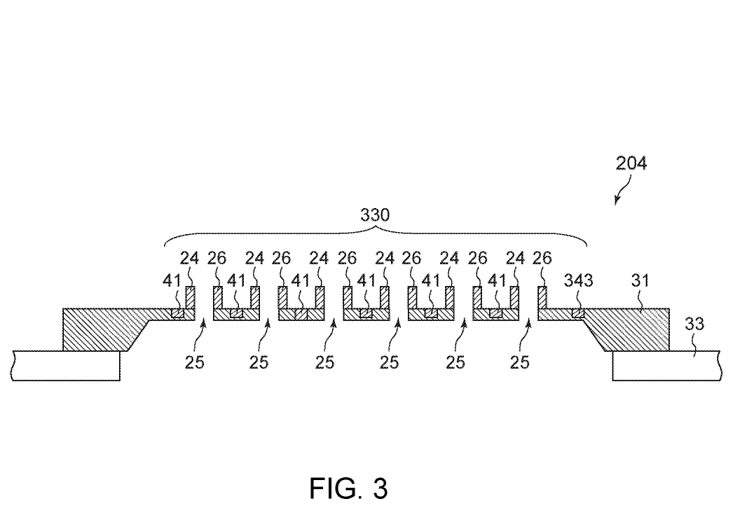

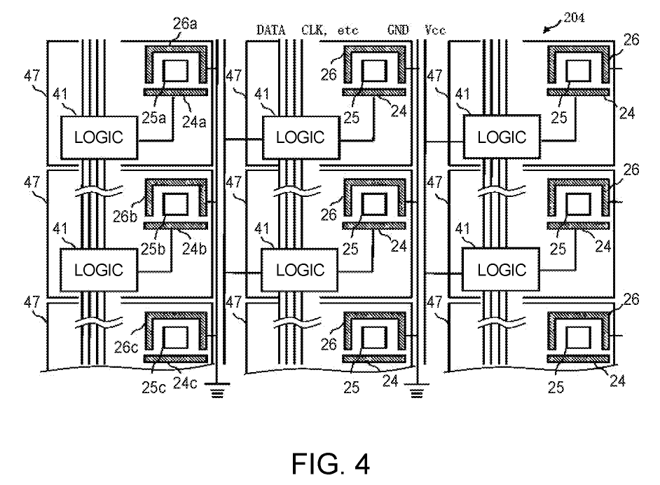

FIG. 3 is a cross-sectional view illustrating a blanking-aperture array substrate 31 of the writing apparatus 100 according to the first embodiment. FIG. 4 is a plan view illustrating an overall configuration of the blanking-aperture array mechanism 204 of the writing apparatus 100 according to the first embodiment. The positional relation among a control electrode 24, a counter electrode 26, a control circuit 41, and a pad 343 are not illustrated to correspond to each other between FIGS. 3 and FIG. 4. As illustrated in FIG. 3, the blanking-aperture array mechanism 204 includes a support 33 and the blanking-aperture array substrate 31 arranged on the support 33. The blanking-aperture array substrate 31 is configured by a semiconductor substrate made of silicon or the like.

The blanking-aperture array substrate 31 is configured to deflect the multiple beams 20. Specifically, the blanking-aperture array substrate 31 has a membrane region 330 at its center. At positions in the membrane region 330 which correspond to the holes 22 in the shaping-aperture array substrate 203, passing holes 25 (i.e., openings) for allowing the multiple beams 20 to pass therethrough, respectively, are provided. The control electrode 24 and the counter electrode 26 of a pair (i.e., a blanker) are arranged at positions that sandwich each passing hole 25 therebetween and are opposed to each other. Further, the control circuit 41 (logic circuit) that applies a deflection voltage to the control electrode 24 for each passing hole 25 is arranged within the blanking-aperture array substrate 31 near that passing hole 25. The counter electrode 26 for each beam is connected to ground.

n bit (e.g., 10 bit) parallel wires for control signal are connected to each control circuit 41. In addition to the n bit parallel wires for irradiation-time control signal (data), wires for clock signal, load signal, shot signal, and power supply are connected to each control circuit 41, for example. As these wires and the like, a part of the parallel wires may be used. As illustrated in FIG. 4, for each beam of the multiple beams 20, an individual blanking mechanism 47 is configured by the control electrode, 24, the counter electrode 26, and the control circuit 41. Further, in the first embodiment, a shift register method is used as a data transfer method, for example. In the shift register method, the multiple beams 20 are divided into a plurality of groups each consisting of a plurality of beams. A plurality of shift registers for the beams in the same group are connected to each other in series. Specifically, the control circuits 41 formed in an array in the membrane region 330 are grouped at a predetermined pitch in the same row or the same column, for example. The control circuits 41 in the same group are connected to each other in series as illustrated in FIG. 4. As illustrated in FIG. 3, in the blanking-aperture array substrate 31, the pad 343 is arranged to correspond to each group of the control circuits 41. To the pad 343, a signal from the deflection control circuit 130 for the control circuits 41 of the corresponding group is transmitted. The signal from the pad 343 arranged for each group is transmitted to the control circuits 41 in the group.

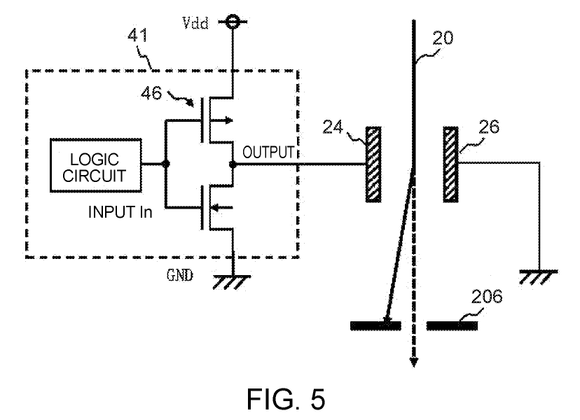

FIG. 5 is a diagram illustrating a configuration of the individual blanking mechanism 47 of the blanking-aperture array mechanism 204 in the writing apparatus 100 according to the first embodiment. In the example illustrated in FIG. 5, an amplifier 46 is arranged in the control circuit 41. More specifically, a CMOS (Complementary MOS) inverter circuit being a switching circuit is arranged as an example of the amplifier 46 in the control circuit 41. To the input (IN) of the CMOS inverter circuit, either the L (low) potential (e.g., the ground potential) lower than a threshold voltage or the H (high) potential (e.g., 1.5 V) equal to or higher than the threshold voltage is applied as a control signal. In a case where the L potential is applied to the input (IN) of the CMOS inverter circuit, the output (OUT) of the CMOS inverter circuit, which is applied to the control circuit 41, becomes a positive potential (Vdd). In this case, the corresponding beam 20 is deflected by an electric field formed by a potential difference between the counter electrode 26 and the ground potential and is blocked by the limiting-aperture substrate 206 (that is, the beam is OFF). On the other hand, in a case where the H potential is applied to the input (IN) of the CMOS inverter circuit (i.e., in an active state), the output (OUT) of the CMOS inverter circuit becomes the ground potential. In this case, there is no potential difference between the counter electrode 26 and the ground potential, and therefore the corresponding beam 20 is not deflected. Accordingly, the corresponding beam 20 passes through the limiting-aperture substrate 206, so that the beam is ON. Blanking control is executed by the control of deflection of the corresponding beam 20 described above.

Each individual blanking mechanism 47 individually controls an irradiation time of a corresponding shot by using a counter circuit (not illustrated) for each beam in accordance with the irradiation-time control signal transferred for that beam.

The shot data generator 111 illustrated in FIG. 1 generates shot data including the shot number of the electron beam based on writing data stored in the storage device 140. The shot number is the serial number corresponding to the number of shots. For example, the shot number 1 is assigned to the first shot, and the shot number 2 is assigned to the second shot. The shot number is associated with the shot position (i.e., the position of writing).

The BAA controller 112 controls the blanking-aperture array substrate 31. Specifically, the BAA controller 112 outputs data instructing ON or OFF of each of the multiple beams 20 to the deflection control circuit 130. The deflection control circuit 130 applies a control signal controlling beam ON or beam OFF to the control circuit 41 based on the data output from the BAA controller 112. That is, the BAA controller 112 executes blanking control of the multiple beams 20 via the deflection control circuit 130.

The irradiation time controller 113 controls the irradiation time of the multiple beams 20. Specifically, the irradiation time controller 113 outputs data instructing the irradiation time of the multiple beams 20 to the deflection control circuit 130. The deflection control circuit 130 applies an irradiation-time control signal to the control circuit 41 based on the data output from the irradiation time controller 113. That is, the irradiation time controller 113 controls the irradiation time of the multiple beams 20 via the deflection control circuit 130.

The deflection controller 114 controls deflection of the multiple beams 20 (i.e., the electron beam) by the main deflector 208 and the sub-deflector 209. Specifically, the deflection controller 114 outputs data instructing a deflection voltage of the main deflector 208 and the sub-deflector 209 to the deflection control circuit 130. The deflection control circuit 130 applies the deflection voltage to the main deflector 208 and the sub-deflector 209 based on the data output from the deflection controller 114 via the DAC amplifier units 132 and 134. That is, the deflection controller 114 controls deflection of the multiple beams 20 by the main deflector 208 and the sub-deflector 209 (i.e., the irradiation position) via the deflection control circuit 130.

The stage controller 115 controls movement of the X-Y stage 105. The stage controller 115 controls the movement of the X-Y stage 105 via the stage control mechanism 138 by applying a control signal controlling the movement of the X-Y stage 105 to the stage control mechanism 138. Control of the movement of the X-Y stage 105 by the stage controller 115 includes control of at least one of the movement amount, movement direction, and movement speed of the X-Y stage 105.

The irradiation controller 116 controls electron beam irradiation by controlling operations of the deflection controller 114 and the stage controller 115 based on the shot data generated by the shot data generator 111. That is, the irradiation controller 116 controls output of the data instructing the deflection voltage by the deflection controller 114, based on the generated shot data. Further, the irradiation controller 116 controls application of the control signal to the stage control mechanism 138 by the stage controller 115, based on the generated shot data. The irradiation controller 116 may further control operations of the BAA controller 112 and the irradiation time controller 113, based on the shot data generated by the shot data generator 111. That is, the irradiation controller 116 may control output of the data instructing beam ON or beam OFF by the BAA controller 112, based on the generated shot data. Further, the irradiation controller 116 may control output of the data instructing the irradiation time of the multiple beams 20 by the irradiation time controller 113, based on the generated shot data.

The shot number may be associated with each of the data instructing beam ON or beam OFF output from the BAA controller 112, the data instructing the irradiation time of the multiple beams 20 output from the irradiation time controller 113, and the data instructing the deflection voltage output from the deflection controller 114.

The storage controller 117 causes the memory 170 to store therein at least the shot number at stop of irradiation of the multiple beams 20, when the irradiation is stopped due to an abnormality occurring in a constituent element other than the irradiation controller 116 among the constituent elements of the writing apparatus 100. The constituent element other than the irradiation controller 116 includes at least one of the shot data generator 111, the deflection controller 114, and the stage controller 115. The constituent element other than the irradiation controller 116 may further include at least one of the blanking-aperture array substrate 31, the BAA controller 112, and the irradiation time controller 113. The storage controller 117 may detect that abnormal stop of the irradiation of the multiple beams 20 has occurred due to the abnormality occurring in the constituent element other than the irradiation controller 116, for example, based on the operating state of the constituent element other than the irradiation controller 116 (e.g., a data retention state).

The initializing portion 118 initializes (i.e., resets) the constituent element other than the irradiation controller 116, when the irradiation of the multiple beams 20 has been stopped due to the abnormality occurring in the constituent element other than the irradiation controller 116. In a case where the constituent element other than the irradiation controller 116 is hardware, the initializing portion 118 initializes that hardware. In a case where the constituent element other than the irradiation controller 116 is software, the initializing portion 118 initializes that software.

In a case where the irradiation of the multiple beams 20 has been stopped due to the abnormality occurring in the constituent element other than the irradiation controller 116, the irradiation controller 116 resumes the electron beam irradiation from the shot number next to the shot number for which the irradiation has been stopped, stored in the memory 170, when a condition for resuming the irradiation of the multiple beams 20 is satisfied. In the first embodiment, the condition for resuming the electron beam irradiation is that initialization by the initializing portion 118 has been done.

The warning portion 119 outputs a warning for notifying of resumption of the irradiation when the irradiation controller 116 resumes the irradiation of the multiple beams 20. The warning portion 119 outputs the warning, for example, by displaying an image, outputting sound, or both of them.

Next, a specific operation example of the writing mechanism 150 is described. The electron beam 200 emitted from the electron gun 201 (emission source) illuminates the entire shaping-aperture array substrate 203 nearly vertically by the illumination lens 202. The rectangular holes 22 (i.e., openings) are formed in the shaping-aperture array substrate 203. The electron beam 200 illuminates a region including all the holes 22. Portions of the electron beam 200 irradiated onto the positions of the holes 22 pass through the holes 22 in the shaping-aperture array substrate 203, respectively, so that the multiple beams having a rectangular shape (i.e., multiple electron beams) 20 are formed, for example. The multiple beams 20 pass through the corresponding blankers of the blanking-aperture array mechanism 204, respectively.

The blanker controlled to make the corresponding beam ON by the BAA controller 112 executes blanking control for the corresponding beam so as to place that beam in the ON state during the irradiation time instructed by the irradiation time controller 113.

The multiple beams 20 passing through the blanking-aperture array mechanism 204 are subjected to size reduction by the reduction lens 205 and then travel toward the central hole formed in the limiting-aperture substrate 206. Here, the blanker controlled to make the corresponding beam OFF by the BAA controller 112 deflects the corresponding beam. As illustrated with a broken line in FIG. 1, the electron beam having been deflected is out of the central hole of the limiting-aperture substrate 206 and is blocked by the limiting-aperture substrate 206. Meanwhile, the blanker controlled to make the corresponding beam ON by the BAA controller 112 does not deflect the corresponding electron beam. The electron beam not having been deflected passes through the central hole of the limiting-aperture substrate 206 as illustrated in FIG. 1. As described above, the limiting-aperture substrate 206 blocks each beam having been deflected to be placed in the beam OFF state by the individual blanking mechanism 47. The beam formed from beam ON to beam OFF and passing through the limiting-aperture substrate 206 forms each beam of one shot. The multiple beams 20 passing through the limiting-aperture substrate 206 are focused by the objective lens 207 to form a pattern image with a desired reduction ratio. The main deflector 208 and the sub-deflector 209 deflect the multiple beams 20 passing through the limiting-aperture substrate 206 to the same direction all together in accordance with deflection control by the deflection controller 114, and cause them to be incident on the respective irradiation positions on the sample 101. Further, during continuous movement of the X-Y stage 105 in accordance with control by the stage controller 115, the deflection controller 114 executes tracking control by deflecting the multiple beams 20 by the main deflector 208 so as to cause the beam irradiation positions to follow the movement of the X-Y stage 105. The multiple beams 20 irradiated at a time are ideally arranged at a pitch obtained by multiplying the arrangement pitch of the holes 22 in the shaping-aperture array substrate 203 by the desired reduction ratio described above.

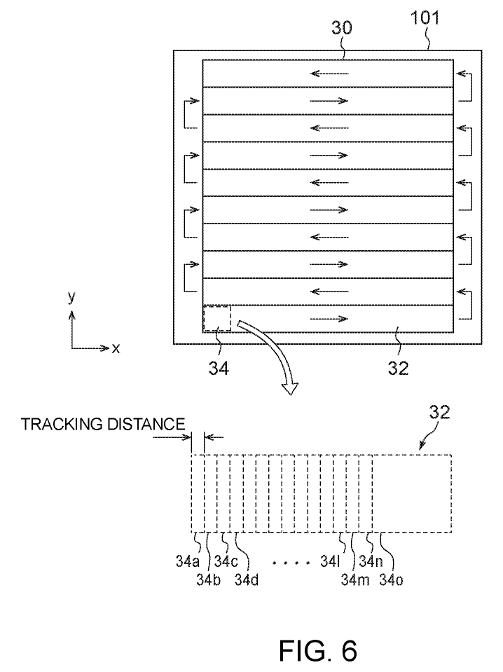

FIG. 6 is a diagram illustrating an example of a writing operation of the writing apparatus 100 according to the first embodiment. As illustrated in FIG. 6, a writing region 30 of the sample 101 is virtually divided into a plurality of strip regions 32 each having a predetermined width in the y direction, for example. First, the X-Y stage 105 is moved in accordance with control by the stage controller 115, adjustment is performed to place an irradiation region 34 that can be irradiated with one shot of the multiple beams 20 at the left end of the first strip region 32 or the further left position, and writing is then started. While writing is performed onto the first strip region 32, the X-Y stage 105 is moved to the -x direction, so that writing is advanced to the x direction relatively, for example. The X-Y stage 105 is continuously moved, for example, at a constant speed. After writing onto the first strip region 32 is finished, the stage position is moved to the -y direction, and then the X-Y stage 105 is moved to the x direction, for example. Accordingly, writing is performed to the -x direction similarly. Those operations are repeated, and writing is performed onto the strip regions 32 in turn. Performing writing while changing the direction alternately can shorten the writing time. However, the writing method is not limited to the case of performing writing while changing the direction alternately. Writing may be advanced to the same direction at the time of writing onto the respective strip regions 32. In a case where the X-Y stage 105 is moved at a constant speed, the speed of continuous movement may be different for each strip. In one shot, the multiple beams formed by passing through the respective holes 22 in the shaping-aperture array substrate 203 form a plurality of shot patterns at a time, the number of which is at most the same number as the number of holes 22.

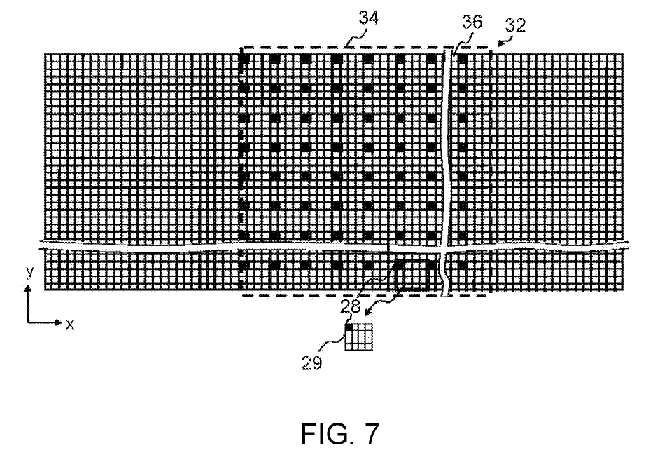

FIG. 7 is a diagram illustrating an example of an irradiation region of the writing apparatus 100 according to the first embodiment and a writing target pixel. In FIG. 7, the strip region 32 is divided into a plurality of mesh regions arranged in mesh and each having a size being the beam size of each of the multiple beams 20, for example. Each mesh region serves as a writing target pixel 36 (a unit irradiation region, an irradiation position, or a writing position). The size of the writing target pixel 36 is not limited to the beam size, and may be any size regardless of the beam size. For example, the size of the writing target pixel 36 may be 1/a of the beam size, where a is an integer of 1 or more. In the example of FIG. 7, the strip region 32 has substantially the same width (i.e., the size in the y direction) as the irradiation region 34 that can be irradiated with one irradiation of the multiple beams 20. The size of the irradiation region 34 in the x direction can be defined by the number of beams in the x direction × the beam pitch in the x direction. The size of the irradiation region 34 in the y direction can be defined by the number of beams in the y direction × the beam pitch in the y direction. In the example of FIG. 7, 500 columns × 500 rows multiple beams are partially omitted to 8 columns × 8 rows multiple beams, for example. In the irradiation region 34, a plurality of pixels 28 (beam writing positions) that can be irradiated with one shot of the multiple beams 20 are illustrated. A pitch between the adjacent pixels 28 on the sample surface is a pitch between beams (beam pitch) of the multiple beams 20. A rectangular region surrounded in the x and y directions to have a size defined by the beam pitches configures one sub-irradiation region 29 (pitch cell). Each sub-irradiation region 29 includes one pixel 28. In the example of FIG. 7, a pixel at an upper left corner of each sub-irradiation region 29 is illustrated as the pixel 28 serving as the beam writing position. Each sub-irradiation region 29 is configured by 4 × 4 pixels, for example.

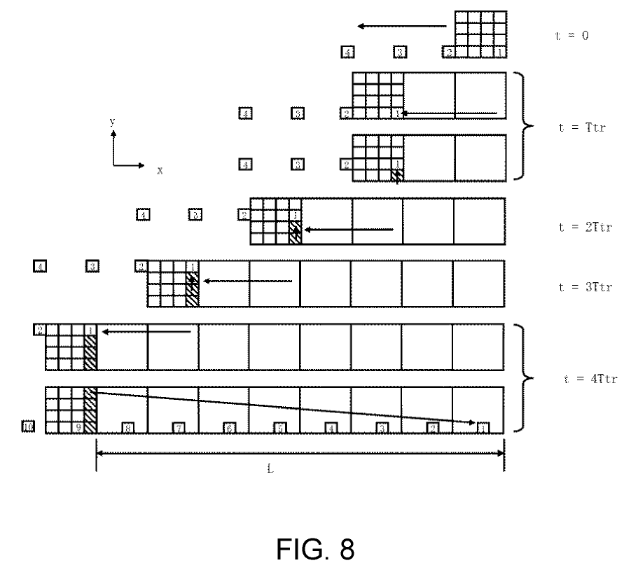

FIG. 8 is a diagram illustrating an example of a multi-writing operation of the writing apparatus 100 according to the first embodiment. FIG. 8 illustrates a part of a grid written by beams of the coordinates (1, 3), (2, 3), (3, 3), ..., (512, 3) in the third row in the y direction among multiple beams writing the strip region 32 illustrated in FIG. 7. In the example of FIG. 8, a case is illustrated in which four pixels are written (exposed) while the X-Y stage 105 moves by a distance of eight beam pitches, for example. During writing (exposure) of these four pixels, the multiple beams 20 are deflected by the main deflector 208 all together in such a manner that the irradiation region 34 is not relatively shifted from the sample 101 due to the movement of the X-Y stage 105. Accordingly, the irradiation region 34 is caused to follow the movement of the X-Y stage 105. In other words, tracking control is executed. In the example of FIG. 8, a case is illustrated in which one tracking cycle is conducted by performing writing (exposure) for four pixels during the movement by eight beam pitches.

Specifically, the stage-position measuring device 139 emits laser to the mirror 210 and receives reflected light from the mirror 210, thereby measuring the position of the X-Y stage 105. The position of the X-Y stage 105 thus measured is output to the control computer 110. In the control computer 110, the irradiation controller 116 outputs information on the position of the X-Y stage 105 to the deflection control circuit 130. In the deflection control circuit 130, calculation is performed to obtain deflection amount data (tracking deflection data) for achieving beam deflection so as to cause the irradiation region to follow the movement of the X-Y stage 105 in accordance with the movement of the X-Y stage 105. The tracking deflection data that is a digital signal is output to the DAC amplifier 134, and the DAC amplifier 134 converts the digital signal to an analog signal, amplifies the analog signal, and applies the amplified analog signal to the main deflector 208 as a tracking deflection voltage.

Subsequently, for a writing time corresponding to each pixel 36 within a maximum writing time Ttr in the irradiation time of each of the multiple beams in the corresponding shot (i.e., divided shots in total), the writing mechanism 150 irradiates the corresponding one of ON beams in the multiple beams 20 to the pixel 36. In the first embodiment, one shot (a shot for one path) is divided into a plurality of divided shots, and these divided shots are done during the operation for the one shot. While the divided shots are regarded as one shot, an operation for each shot is described next.

In the example of FIG. 8, at the time t=2Ttr, the writing target pixel is shifted by collective deflection of the multiple beams by the sub-deflector 209 from the first pixel from the right in the second row from the bottom in the grid of interest 29 to the first pixel from the right in the third row from the bottom. Since the X-Y stage 105 continues to move during this shift, the tracking operation continues. Subsequently, beam irradiation for the third shot is performed for the first pixel from the right in the third row from the bottom in the grid of interest 29 by the beam (1) of the coordinates (1, 3) from the time t=2Ttr to the time t=3Ttr, for example. The X-Y stage 105 moves by two beam pitches to the -x direction from the time t=2Ttr to the time t=3Ttr, for example. During this period, the tracking operation continues. At the time t=3Ttr, the writing target pixel is shifted by collective deflection of the multiple beams by the sub-deflector 209 from the first pixel from the right in the third row from the bottom in the grid of interest 29 to the first pixel from the right in the fourth row from the bottom. Since the X-Y stage 105 continues to move during this shift, the tracking operation continues. Subsequently, beam irradiation for the fourth shot is performed for the first pixel from the right in the fourth row from the bottom in the grid of interest 29 by the beam (1) of the coordinates (1, 3) from the time t=3Ttr to the time t=4Ttr, for example. The X-Y stage 105 moves by two beam pitches to the -x direction from the time t=3Ttr to the time t=4Ttr, for example. During this period, the tracking operation continues. With the above operations, writing onto the first column of pixels from the right in the grid of interest 29 is finished.

In the example of FIG. 8, beam irradiation is performed while the beam is switched to each of the beam writing positions after the writing target pixel has been shifted from the initial position three times, and thereafter the DAC amplifier 134 resets beam deflection for tracking control, thereby returning the tracking position to a tracking start position at which tracking control has been started. In other words, the tracking position is returned to the opposite direction to the stage moving direction. In the example of FIG. 8, at the time t=4Ttr, tracking in the grid of interest 29 is stopped, and the beam is returned to the next grid of interest shifted to the x direction by eight beam pitches. Although the description is provided as to the beam (1) of the coordinates (1, 3) in the example of FIG. 8, writing by a beam of another coordinate is similarly performed for a grid corresponding to the beam. That is, at t=4Ttr, a beam of the coordinates (n, m) finishes writing onto the first column of pixels from the right in the grid corresponding to the beam. For example, the beam (2) of the coordinates (2, 3) finishes writing onto the first column of pixels from the right in the grid adjacent in the -x direction to the grid of interest 29 for the beam (1) in FIG. 8.

Writing onto the first column of pixels from the right in each grid has been finished. Therefore, first, in the next tracking cycle after tracking reset, the sub-deflector 209 performs deflection to align (shift) the beam writing position with (to) the second pixel from the right in the lowermost row in each grid.

As described above, in a state where the irradiation region 34 is controlled by the main deflector 208 in such a manner that its relative position to the sample 101 is the same position during the same tracking cycle, each shot (the divided shots) for the corresponding path is performed while the shot position is shifted pixel by pixel by the sub-deflector 209. After one tracking cycle is finished, the tracking position of the irradiation region 34 is returned, the first shot position is aligned with the position shifted by, for example, one pixel as illustrated in the lower part of FIG. 6, and then each shot is performed while next tracking control is executed and the shot position is shifted pixel by pixel by the sub-deflector 209. By repeating these operations during writing onto the strip region 32, the position of the irradiation region 34 is moved in the order of irradiation regions 34a to 34o, and writing onto the corresponding strip region is performed.

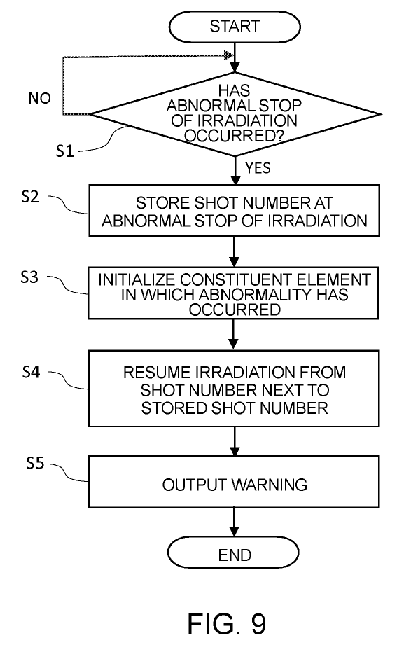

Next, an operation example of the writing apparatus 100 according to the first embodiment is described. FIG. 9 is a flowchart illustrating the operation example of the writing apparatus 100 according to the first embodiment. In an initial state in FIG. 9, it is assumed that the writing mechanism 150 irradiates the multiple beams 20 (i.e., performs writing) onto the sample 101 under control by the irradiation controller 116. From the initial state, the storage controller 117 determines whether abnormal stop of irradiation of the multiple beams 20 has occurred due to an abnormality occurring in a constituent element other than the irradiation controller 116 (Step S1). For example, the storage controller 117 determines whether the abnormal stop of the irradiation of the multiple beams 20 has occurred based on the operating state of the constituent element other than the irradiation controller 116 (e.g., a data retention state).

In a case where the abnormal stop has occurred (YES at Step S1), the storage controller 117 causes the memory 170 to store therein the shot number at the abnormal stop of irradiation (Step S2). In a case where the abnormal stop has not occurred (NO at Step S1), the storage controller 117 repeats determination whether the abnormal stop of the irradiation of the multiple beams 20 has occurred (Step S1).

After the shot number at the abnormal stop of irradiation is stored, the initializing portion 118 initializes the constituent element other than the irradiation controller 116, in which the abnormality has occurred (Step S3).

After initialization of the constituent element other than the irradiation controller 116, the irradiation controller 116 starts the irradiation from the shot number next to the shot number stored in the memory 170 (Step S4).

After the irradiation is resumed, the warning portion 119 outputs a warning (Step S5).

As described above, in the first embodiment, when electron beam irradiation is stopped due to an abnormality occurring in a constituent element other than the irradiation controller 116, the storage controller 117 causes the memory 170 to store therein at least the shot number at the stop of irradiation. Further, when a condition for resuming the electron beam irradiation is satisfied, the irradiation controller 116 resumes the electron beam irradiation from the shot number next to the shot number for which the irradiation has been stopped and which has been stored in the memory 170.

Accordingly, the electron beam irradiation (i.e., writing) onto the sample 101, which has been abnormally ended, can be resumed appropriately.

In the first embodiment, the condition for resuming the electron beam irradiation is that initialization of the constituent element other than the irradiation controller 116 by the initializing portion 118 has been done.

Accordingly, after the abnormality that has occurred in the constituent element other than the irradiation controller 116 is resolved by initialization by the initializing portion 118, it is possible to resume writing onto the sample 101, which has been abnormally ended, more appropriately.

Furthermore, in the first embodiment, the warning portion 119 outputs a warning when the electron beam irradiation is resumed.

Accordingly, it is possible to cause a user to recognize resumption of the electron beam irradiation, and therefore convenience can be improved.

### Second embodiment

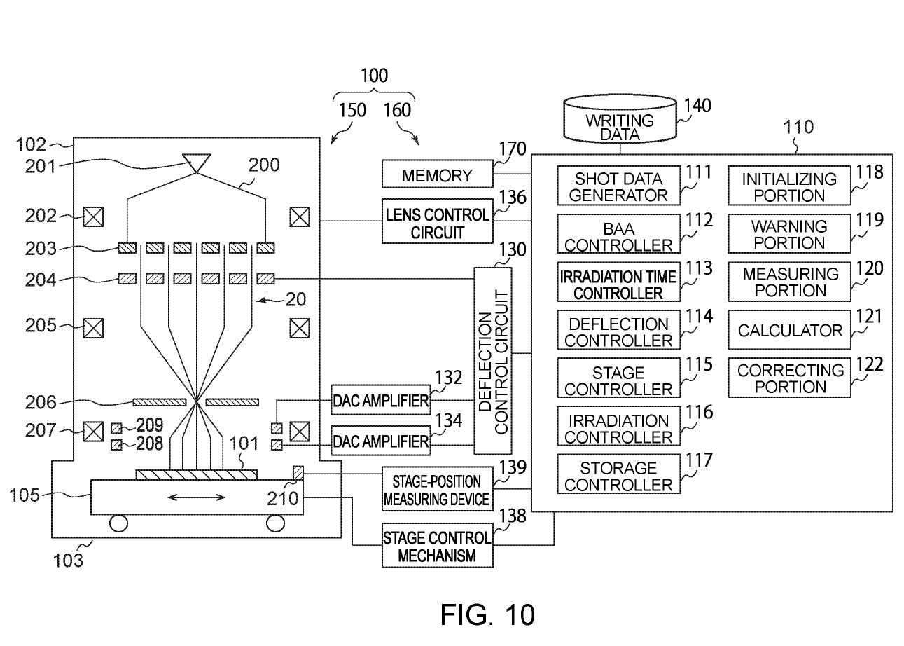

Next, a second embodiment in which an irradiation condition is corrected based on at least one of the temperature and the charge amount on the sample 101 is described, focusing on differences from the embodiment described above. FIG. 10 is a diagram illustrating a configuration example of the writing apparatus 100 according to the second embodiment. As illustrated in FIG. 10, the control computer 110 of the writing apparatus 100 according to the second embodiment includes a measuring portion 120, a calculator 121, and a correcting portion 122 in addition to the configuration in FIG. 1.

The measuring portion 120 measures the beam drift amount. The measuring portion 120 may measure the beam drift amount by scanning a cross-shaped mark provided on the X-Y stage 105 with an electron beam and performing detection as described in Japanese Patent Application Laid-Open No. 2007-43083, for example.

The calculator 121 calculates at least one of the temperature and the charge amount on the sample 101. For example, the calculator 121 may calculate the temperature on the sample 101 by using a dose statistical value Dij and a thermal spread function PSF (i.e., a thermal diffusion equation) and calculating the effective temperature (k, l) of a mesh region of interest, as described in International Publication WO 2023/209825. Further, the calculator 121 may calculate the charge amount by calculating the charge amount distribution C(x, y) from the irradiation amount distribution E(x, y) and a fog electron amount distribution F(x, y, σ) by using a function (E, F), as described in Japanese Patent Application Laid-Open No. 2015-138882, for example.

The correcting portion 122 corrects the irradiation condition based on at least one of the temperature and the charge amount calculated by the calculator 121.

The irradiation controller 116 controls irradiation in accordance with the irradiation condition corrected by the correcting portion 122.

The calculator 121 recalculates at least one of the temperature and the charge amount, considering a time of irradiation stop, in a case where irradiation has been stopped due to an abnormality occurring in a constituent element other than the irradiation controller 116.

The correcting portion 122 recorrects the irradiation condition based on at least one of the temperature and the charge amount recalculated by the calculator 121.

The irradiation controller 116 controls the resumed irradiation in accordance with the irradiation condition recorrected by the correcting portion 122.

The correcting portion 122 may correct the dose as the irradiation condition based on the temperature calculated by the calculator 121. Further, the correcting portion 122 may recorrect the dose based on the temperature recalculated by the calculator 121. For example, the correcting portion 122 may correct and recorrect the dose based on the effective temperature (k, l) by using the method described in International Publication WO 2023/209825.

The correcting portion 122 may correct an irradiation position as the irradiation condition based on the charge amount calculated by the calculator 121. The correcting portion 122 may recorrect the irradiation position based on the charge amount recalculated by the calculator 121. For example, the correcting portion 122 may correct and recorrect the irradiation position (i.e., the pixel position) based on the charge amount by using the method described in Japanese Patent Application Laid-Open No. 2015-138882.

The correcting portion 122 may correct the irradiation position further based on the beam drift amount measured by the measuring portion 120. The correcting portion 122 may recorrect the irradiation position based on the beam drift amount remeasured by the measuring portion 120, in a case where the irradiation has been stopped due to the abnormality that has occurred in the constituent element other than the irradiation controller 116.

The correcting portion 122 may recorrect the irradiation condition, considering the attenuation amount of at least one of the temperature and the charge amount in accordance with the stop time, before at least one of the temperature and the change amount recalculated by the calculator 121 returns to a reference state. In this case, it is possible to recorrect the irradiation condition promptly and appropriately.

Alternatively, the correcting portion 122 may recorrect the irradiation condition, after at least one of the temperature and the charge amount recalculated by the calculator 121 returns to the reference state. In this case, it is possible to appropriately recorrect the irradiation condition after the influence of the abnormal stop of irradiation is eliminated.

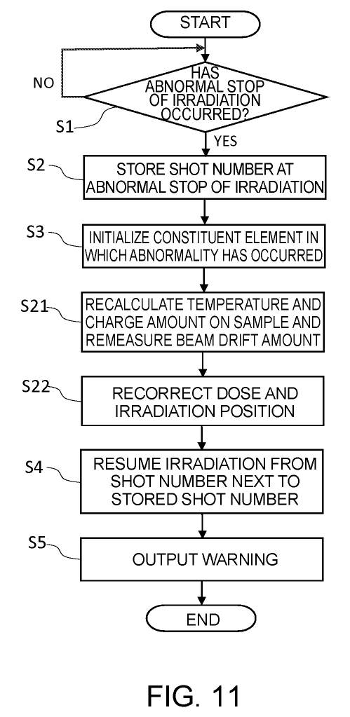

Next, an operation example of the writing apparatus 100 according to the second embodiment is described. FIG. 11 is a flowchart illustrating the operation example of the writing apparatus 100 according to the second embodiment. It is assumed that in an initial state before the flowchart of FIG. 11 is started, the calculator 121 has calculated the temperature and the charge amount on the sample 101. In addition, it is assumed that the measuring portion 120 has measured the beam drift amount. Further, it is assumed that the correcting portion 122 has corrected the dose and the irradiation position based on the temperature, the charge amount, and the beam drift amount.

As illustrated in FIG. 11, in the second embodiment, after initialization by the initializing portion 118, the calculator 121 recalculates the temperature and the charge amount on the sample 101. The measuring portion 120 remeasures the beam drift amount (Step S21).

After recalculation of the temperature and the charge amount and remeasurement of the beam drift amount, the correcting portion 122 recorrects the dose and the irradiation position based on the temperature, the charge amount, and the beam drift amount (Step S22).

As described above, according to the second embodiment, the dose and the irradiation position can be recorrected based on the temperature, the charge amount, and the beam drift amount. Accordingly, it is possible to improve the accuracy of electron beam irradiation, considering the influences of resist heating and charging.

### Third embodiment

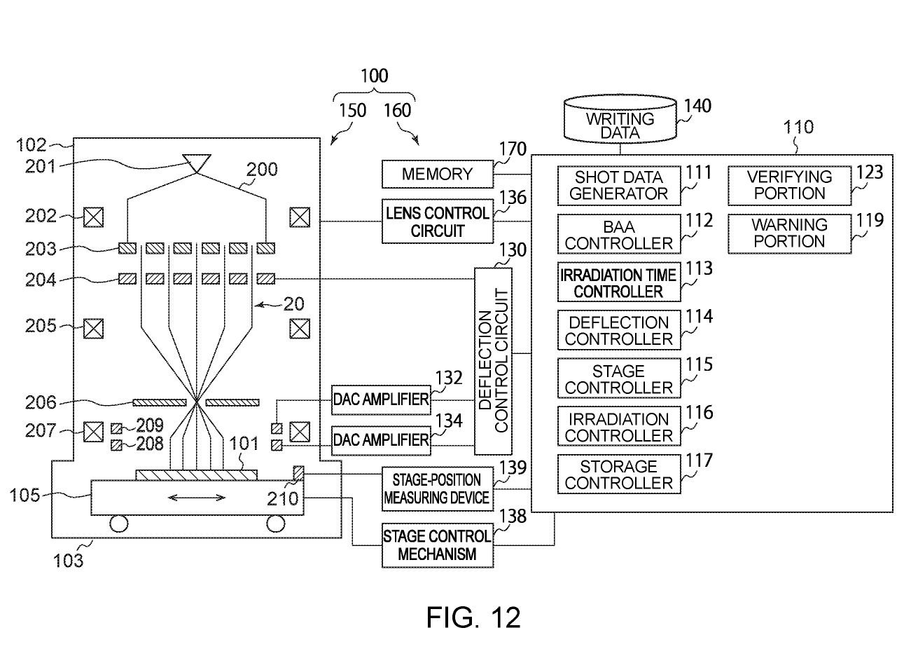

Next, a third embodiment in which electron beam irradiation is resumed based on a verification result of a constituent element other than the irradiation controller 116 is described, focusing on differences from the embodiments described above. FIG. 12 is a diagram illustrating a configuration example of the writing apparatus 100 according to the third embodiment. As illustrated in FIG. 12, the control computer 110 of the writing apparatus 100 according to the third embodiment further includes a verifying portion 123 in addition to the configuration in FIG. 1.

The verifying portion 123 verifies an operation of the constituent element other than the irradiation controller 16 based on test writing data. In the third embodiment, a condition for resuming electron beam irradiation is that the operation of the constituent element other than the irradiation controller 16 verified by the verifying portion 123 is normal.

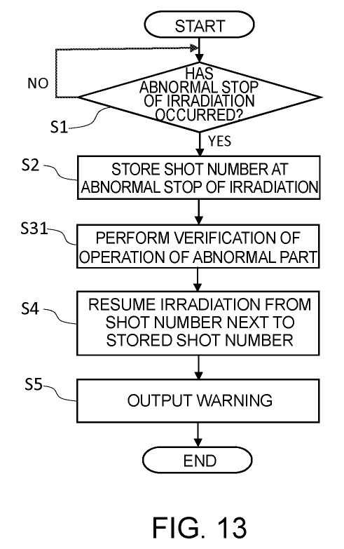

Next, an operation example of the writing apparatus 100 according to the third embodiment is described. FIG. 13 is a flowchart illustrating the operation example of the writing apparatus 100 according to the third embodiment. As illustrated in FIG. 13, in the third embodiment, the verifying portion 123 performs verification of an operation of an abnormal part (Step S31), after the shot number at the abnormal stop of irradiation is stored.

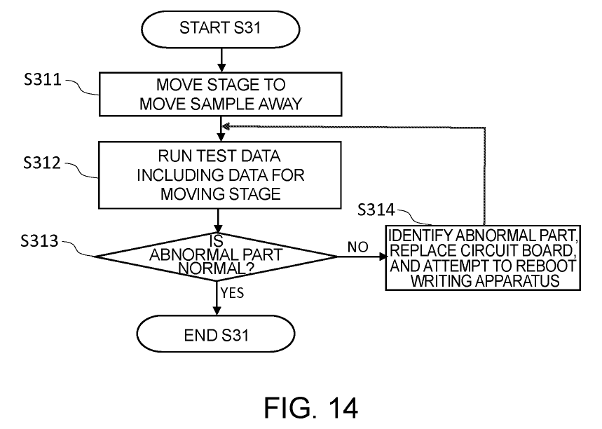

FIG. 14 is a flowchart illustrating the operation example of the writing apparatus 100 according to the third embodiment for describing Step S31 in FIG. 13 in further detail. As illustrated in FIG. 14, in the operation verification, the verifying portion 123 moves the X-Y stage 105 to move the sample 101 away from the irradiation position of the electron beam (Step S311).

After the X-Y stage 105 is moved away, the verifying portion 123 runs test data including data for moving the X-Y stage 105, to the writing apparatus 100 (Step S312). Since only running test data is performed, actual irradiation of the multiple beams 20 by the writing apparatus 100 is not performed although the X-Y stage 105 is moved.

After running the test data, the verifying portion 123 determines, based on the flow of test data in an abnormal part, whether the abnormal part is normal (Step S313).

In a case where the abnormal part is normal (YES at Step S313), the verification ends. On the other hand, in a case where the abnormal part is not normal (NO at Step S313), the verifying portion 123 identifies the abnormal part. In addition, circuit board replacement (i.e., parts replacement) in the abnormal part by a user, an attempt to reboot the writing apparatus 100 after the circuit board replacement, and the like are made (Step S314).

As described above, according to the third embodiment, the irradiation controller 116 resumes electron beam irradiation in a case where the operation of the constituent element other than the irradiation controller 116, which has been verified by the verifying portion 123 is normal.

Accordingly, it is possible to appropriately resume electron beam irradiation after confirming that an abnormality occurring in a constituent element other than the irradiation controller 116 has been resolved by verification by the verifying portion 123.

### First modification of third embodiment

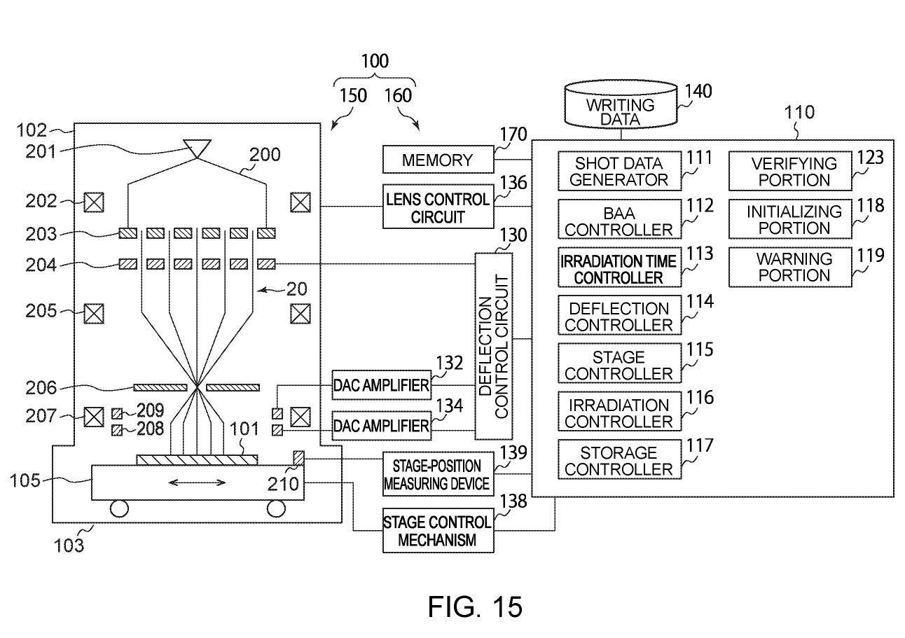

Next, a first modification of the third embodiment which initializes a part in which an abnormality has occurred is described, focusing on differences from the embodiments described above. FIG. 15 is a diagram illustrating a configuration of the writing apparatus 100 according to the first modification of the third embodiment.

In the example illustrated in FIG. 15, the control computer 110 of the writing apparatus 100 includes the initializing portion 118 already described, in addition to the configuration illustrated in FIG. 12.

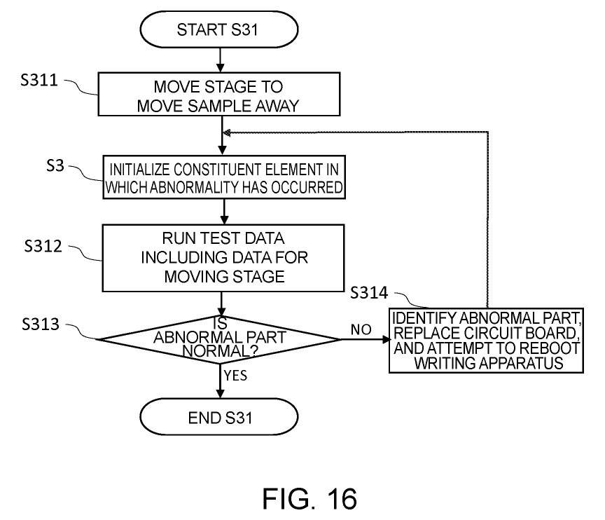

FIG. 16 is a flowchart illustrating an operation example of the writing apparatus 100 according to the first modification of the third embodiment. In the example illustrated in FIG. 16, in operation verification of an abnormal part (Step S31), the initializing portion 118 initializes the constituent element in which an abnormality has occurred (Step S3) after the verifying portion 123 moves the X-Y stage 105 to move the sample 101 away. After initialization of the constituent element in which the abnormality has occurred, the verifying portion 123 runs test data including data for moving the X-Y stage 105 (Step S312).

According to the example illustrated in FIGS. 15 and 16, it is possible to increase the possibility of resuming irradiation by initializing a constituent element in which an abnormality has occurred.

### Second modification of third embodiment

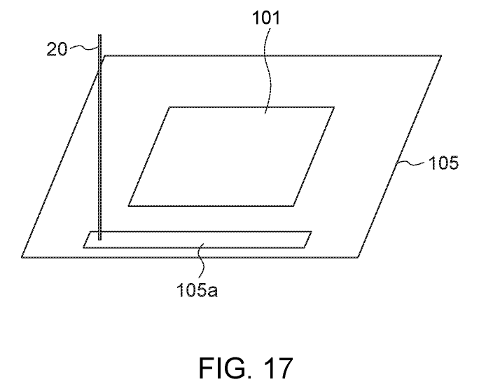

Next, a second modification of the third embodiment which performs a simulated irradiation operation is described, focusing on differences from the embodiments described above. FIG. 17 is a diagram illustrating a configuration of the writing apparatus 100 according to the second modification of the third embodiment.

In the example illustrated in FIG. 17, operation verification of an abnormal part by the verifying portion 123 includes a simulated irradiation operation that simulates irradiation of the multiple beams 20. The X-Y stage 105 has a verification area 105a used for the simulated irradiation operation. In the example illustrated in FIG. 17, the verification area 105a is arranged outside the area of the X-Y stage 105 where the sample 101 is to be placed.

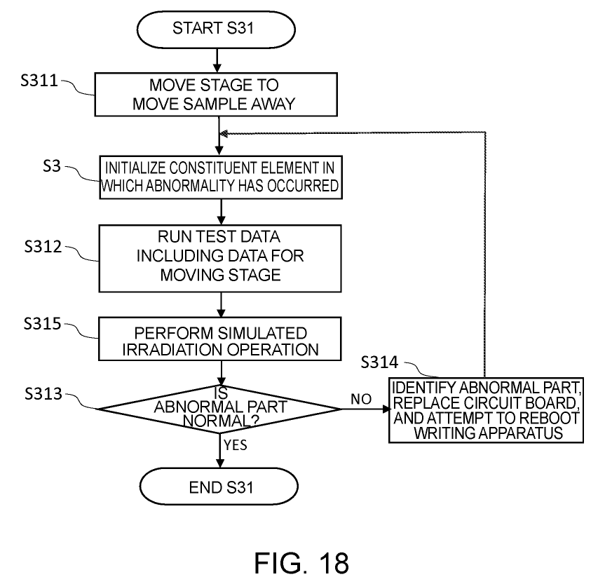

FIG. 18 is a flowchart illustrating an operation example of the writing apparatus 100 according to the second modification of the third embodiment. In the example illustrated in FIG. 18, the verifying portion 123 runs test data and then performs the simulated irradiation operation using the verification area 105a (Step S315).

In the example illustrated in FIGS. 17 and 18, it is possible to perform operation verification of an abnormal part more appropriately by performing a simulated irradiation operation.

### Fourth embodiment

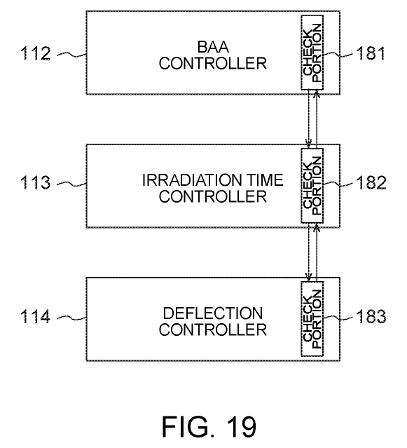

Next, a fourth embodiment that checks data consistency is described, focusing on differences from the embodiments described above. FIG. 19 is a diagram illustrating a configuration of the writing apparatus 100 according to the fourth embodiment.

As illustrated in FIG. 19, in the fourth embodiment, the BAA controller 112, the irradiation time controller 113, and the deflection controller 114 include check portions 181 to 183 on the output stages thereof, respectively, which check consistency among data output from the respective controllers 112 to 114. The check portions 181 to 183 each check consistency among the data output from the BAA controller 112, the data output from the irradiation time controller 113, and the data output from the deflection controller 114. The data output from the BAA controller 112 may be the data instructing beam ON or beam OFF described above. Th data output from the irradiation time controller 113 may be the data instructing the time of irradiation of the multiple beams 20 described above. The data output from the deflection controller 114 may be the data instructing the deflection voltage (i.e., the irradiation position) described above. The check portions 181 to 183 may check consistency based on whether the shot numbers associated with the respective data output from the BAA controller 112, the irradiation time controller 113, and the deflection controller 114 are consistent with one another.

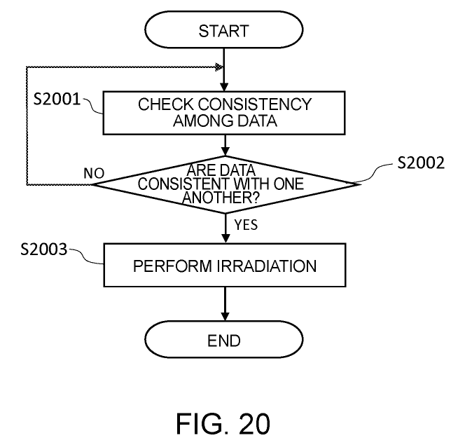

FIG. 20 is a flowchart of an operation example of the writing apparatus 100 according to the fourth embodiment. In the example illustrated in FIG. 20, the check portions 181 to 183 check consistency among data output from the BAA controller 112, data output from the irradiation time controller 113, and data output from the deflection controller 114 (Step S2001).

In a case where the data are consistent with one another (YES at Step S2002), the irradiation controller 116 irradiates the multiple beams 20 (Step S2003). On the other hand, in a case where the data are inconsistent with one another (NO at Step S2002), the check portions 181 to 183 repeat check of consistency (Step S2001). The steps illustrated in FIG. 20 (Steps S2001 to S2003) are conducted before the step of determining whether abnormal stop of irradiation has occurred (Step S1) illustrated in FIG. 9 and other drawings. In addition, the steps illustrated in FIG. 20 (Steps S2001 to S2003) are also conducted after the step of resuming the irradiation (Step S4) illustrated in FIG. 9 and other drawings.

The irradiation controller 116 cannot appropriately control irradiation of the multiple beams 20, unless all the BAA controller 112, the irradiation time controller 113, and the deflection controller 114 perform desired operations. For example, unless the BAA controller 112 performs its desired operation, an electron beam that is to be turned off is irradiated to the sample 101 as a leakage beam. Further, in a case where an electron beam is irradiated to a desired coordinate although the deflection controller 114 has an abnormality, for example, a pattern error occurs even if the irradiation is resumed after the abnormality in the deflection controller 114 is resolved.

On the other hand, according to the fourth embodiment, in a case where the check portions 181 to 183 have confirmed that the data of the BAA controller 112, the data of the irradiation time controller 113, and the data of the deflection controller 114 are consistent with one another, there is no problem even if it is determined that the BAA controller 112, the irradiation time controller 113, and the deflection controller 114 operate normally, and therefore the irradiation controller 116 irradiates the multiple beams 20. Accordingly, since the multiple beams 20 can be irradiated after it has been confirmed that all the BAA controller 112, the irradiation time controller 113, and the deflection controller 114 perform desired operations, irradiation of the multiple beams 20 can be controlled appropriately.

### Modification of fourth embodiment

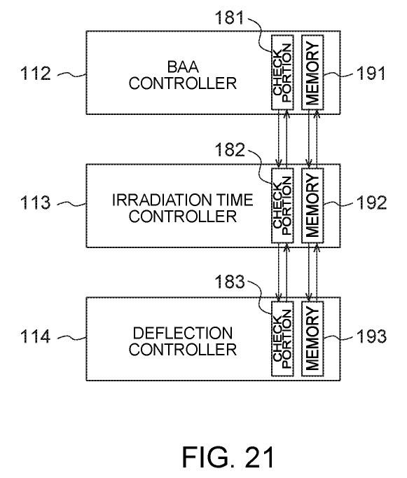

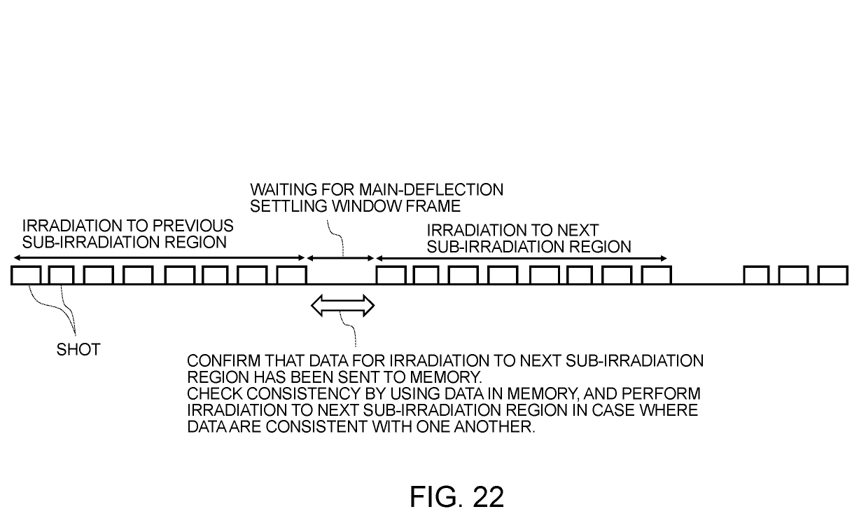

Next, a modification of the fourth embodiment which checks consistency by using data stored in a memory is described, focusing on differences from the embodiments described above. FIG. 21 is a diagram illustrating a configuration of the writing apparatus 100 according to the modification of the fourth embodiment. FIG. 22 is a diagram illustrating an operation example of the writing apparatus 100 according to the modification of the fourth embodiment.

In the example illustrated in FIG. 21, the BAA controller 112, the irradiation time controller 113, and the deflection controller 114 include memories 191 to 193 (i.e., second storages) on the output stages thereof, respectively, each of which stores therein data output from the corresponding one of the controllers 112 to 114, the storing data amount being larger than the data amount for one shot. The data amount of the data stored in each of the memories 191 to 193 may be the data amount corresponding to the sub-irradiation region 29 described above. Storing data in the memories 191 to 193 may be controlled by the storage controller 117. The check portions 181 to 183 check consistency by using the data stored in the memories 191 to 193.

More specifically, in the example illustrated in FIG. 22, in a main-deflection settling window-frame waiting time, the check portions 181 to 183 confirm that data for irradiation onto the next sub-irradiation region 29 has been sent to the memories 191 to 193. The check portions 181 to 183 check consistency by using the data in the memories 191 to 193. In a case where the data are consistent with one another, the irradiation controller 116 performs irradiation onto the next sub-irradiation region 29.

According to the examples illustrated in FIGS. 21 and 22, it is possible to check the consistency by using the data stored in the memories 191 to 193 and therefore the handshake among the check portions 181 to 183 for each shot is not required. As a result, reduction in throughput can be prevented.

The embodiments described above have been presented by way of example only and are not intended to limit the scope of the invention. The embodiments can be implemented in a variety of other forms, and various omissions, substitutions and changes can be made without departing from the spirit of the invention. The embodiments and modifications thereof are included in the scope of invention described in the claims and their equivalents as well as the scope and the spirit of the invention.

1. A charged-particle beam irradiation apparatus comprising:
a deflector configured to deflect a charged-particle beam irradiated onto a sample placed on a stage;
a shot data generator configured to generate shot data including a shot number of the charged-particle beam based on writing data;
a deflection controller configured to control deflection of the charged-particle beam by the deflector;
a stage controller configured to control movement of the stage;
an irradiation controller configured to control irradiation of the charged-particle beam by controlling operations of the deflection controller and the stage controller based on the shot data generated by the shot data generator; and
a storage controller configured to, when the irradiation of the charged-particle beam is stopped due to an abnormality occurring in a constituent element that is other than the irradiation controller among a plurality of constituent elements of the charged-particle beam irradiation apparatus and that includes at least one of the shot data generator, the deflection controller, and the stage controller, cause a storage to store therein at least the shot number at the stop of the irradiation, wherein
when a condition for resuming the irradiation of the charged-particle beam is satisfied, the irradiation controller resumes the irradiation of the charged-particle beam from a shot number next to the shot number stored in the storage at the stop of the irradiation.

2. The apparatus of claim 1, further comprising an initializing portion configured to initialize the constituent element other than the irradiation controller, wherein
the condition for resuming the irradiation of the charged-particle beam is that initialization by the initializing portion has been done.

3. The apparatus of claim 1, further comprising a verifying portion configured to verify an operation of the constituent element other than the irradiation controller based on test writing data, wherein
the condition for resuming the irradiation of the charged-particle beam is that the operation of the constituent element other than the irradiation controller, verified by the verifying portion, is normal.

4. The apparatus of claim 1, further comprising a warning portion configured to output a warning when the irradiation of the charged-particle beam is resumed.

5. The apparatus of claim 1, further comprising:
a calculator configured to calculate at least one of a temperature and a charge amount on the sample; and
a correcting portion configured to correct an irradiation condition based on at least one of the temperature and the charge amount calculated by the calculator, wherein
the irradiation controller controls the irradiation in accordance with the irradiation condition corrected by the correcting portion,
the calculator recalculates at least one of the temperature and the charge amount, considering a stop time of the irradiation, in a case where the irradiation has been stopped due to the abnormality,
the correcting portion recorrects the irradiation condition based on at least one of the temperature and the charge amount recalculated by the calculator, and
the irradiation controller resumes the irradiation in accordance with the irradiation condition recorrected by the correcting portion.

6. The apparatus of claim 5, wherein the correcting portion corrects a dose as the irradiation condition based on the temperature calculated by the calculator and recorrects the dose based on the temperature recalculated by the calculator.

7. The apparatus of claim 5, wherein the correcting portion corrects an irradiation position as the irradiation condition based on the charge amount calculated by the calculator and recorrects the irradiation position based on the charge amount recalculated by the calculator.

8. The apparatus of claim 7, further comprising a measuring portion configured to measure a beam drift amount, wherein
the correcting portion corrects the irradiation position further based on the beam drift amount measured by the measuring portion,
the measuring portion remeasures the beam drift amount in a case where the irradiation has been stopped due to the abnormality, and
the correcting portion recorrects the irradiation position based on the beam drift amount remeasured by the measuring portion in a case where the irradiation has been stopped due to the abnormality.

9. A charged-particle beam irradiation method irradiating a charged-particle beam by using a charged-particle beam irradiation apparatus including:
a deflector configured to deflect the charged-particle beam irradiated onto a sample placed on a stage;
a shot data generator configured to generate shot data including a shot number of the charged-particle beam based on writing data;
a deflection controller configured to control deflection of the charged-particle beam by the deflector;
a stage controller configured to control movement of the stage; and
an irradiation controller configured to control irradiation of the charged-particle beam by controlling operations of the deflection controller and the stage controller based on the shot data generated by the shot data generator, wherein
the irradiation of the charged-particle beam includes:
when the irradiation of the charged-particle beam is stopped due to an abnormality occurring in a constituent element that is other than the irradiation controller among a plurality of constituent elements of the charged-particle beam irradiation apparatus and that includes at least one of the shot data generator, the deflection controller, and the stage controller, causing a storage to store therein at least the shot number at the stop of the irradiation; and
when a condition for resuming the irradiation of the charged-particle beam is satisfied, resuming the irradiation of the charged-particle beam from a shot number next to the shot number stored in the storage at the stop of the irradiation.
